(19) United States
(12) Patent Application Publication
(10) Pub. No.: US 2008/0148861 A1
(43) Pub. Date: Jun. 26, 2008

(54) Semiconductor Sensor Component Comprising Protected Feeders, and Method for the Production Thereof

(76) Inventor: Gottfried Beer, Nittendorf (DE)

Correspondence Address: HARNESS, DICKEY & PIERCE, P.L.C., P.O.BOX 8910, RESTON, VA, 20195, US

(21) Appl. No.: 11/795,594

(22) PCT Filed: Jan. 17, 2006
(86) PCT No.: PCT/EP06/50243

§ 371 Date: Jul. 19, 2007

(30) Foreign Application Priority Data
Jan. 20, 2005 (DE) 10-2005-002-814.4

(51) Int. Cl. G01L 9/00; H01L 21/00

(52) U.S. Cl. 73/754; 438/50; 257/E21.001

(57) ABSTRACT

A semiconductor sensor component including protected feeders and a method for the production thereof are disclosed. The semiconductor component encompasses a sensor chip with a sensor area. The sensor chip is disposed in a two-part housing that accommodates the sensor chip in a bottom housing part. A seal that surrounds the sensor area is arranged between the bottom housing part and a top housing part. The seal, in at least one embodiment, also extends across the feeders, wherefore the feeders are configured as flat printed metal-containing strip conductors which adhere to the bottom housing part, the sensor chip, and a transition zone that is made of different materials.

### PRIORITY STATEMENT

This application is the national phase under 35 U.S.C. §371 of PCT International Application No. PCT/EP2006/050243 which has an International filing date of Jan. 16, 2006, which designated the United States of America and which claims priority on German Patent Application number 10 2005 002 814.4 filed Jan. 20, 2005, the entire contents of which are hereby incorporated herein by reference.

### FIELD

At least one embodiment of the invention relates to a semiconductor sensor component having protected leads. For example, the semiconductor sensor component may include a sensor chip having a sensor surface in a sensor region. While the sensor surface in the sensor region is intended for supply and discharge of the medium in the housing, in at least one embodiment, supply and signal currents are conducted to the sensor region and away from the sensor region via the protected leads.

### BACKGROUND

The sealing of housing parts of a semiconductor sensor component, having openings and/or cavities for fluids or gaseous media to be studied, is problematic in the region of the protected leads to the sensor region of the sensor chip in conventional semiconductor sensor components. This is particularly true when the corrosion-susceptible bonding connections and bonding wires between the sensor chip and the housing are embedded in a rubber-elastic insulating and protecting cover compound, which is known by the name globtop and entails a considerable space requirement, particularly when the cover compound must be higher than the grinding height of the bonding wires. Furthermore, the globtop cannot be applied in a locally limited fashion, which likewise leads to a considerable space requirement.

Document DE 103 04 775 B3 discloses a sensor system comprising a biosensor in chip card format and a measuring instrument, in which the sealing and the media delivery are undertaken by the measuring instrument, so that the sealing problem is circumvented or transferred to the measuring instrument.

### SUMMARY

At least one embodiment of the invention provides a semiconductor sensor component having protected leads to a sensor chip, in which the sealing problem is reduced and which is fully functional without a measuring instrument and can carry out chemical, biochemical and/or physical analyses, like a multifunctional chip laboratory.

At least one embodiment of the invention provides a semiconductor sensor component having protected leads, the semiconductor sensor component comprising a sensor chip which has a sensor surface on its active upper side. The sensor chip is arranged in a two-part housing. The sensor housing includes an upper housing part partially covering the sensor chip and a lower housing part carrying the sensor chip. The sensor surface of the sensor chip between the upper housing part and the lower housing part is connectable to the environment via at least one opening in the upper housing part and/or in the lower housing part.

A seal, which encloses and protects the sensor surface and covers the leads to the sensor surface, is arranged between the upper housing part and the lower housing part. The leads are metal-containing pasted conductor tracks which are arranged on the lower housing part and the sensor chip and on transition regions made of different materials and have an insulating cover with a thickness of a few micrometers in the sealed sensor region.

The semiconductor sensor component, of at least one embodiment, has the advantage that the flat leads can be protected in a locally limited fashion in the sensor region without a high application thickness so that they are suitable, for example, for fully electronic DNA sensors or for electrical “labs on chip” or for μTAS (micro total analysis system) as well as for gas sensors and chemical sensors, short circuits and corrosion of the leads being reliably prevented. On the other hand, an application pressure can be applied between the two housing parts for effective sealing, without the leads becoming damaged. The sealing can consequently be routed over the connection region of the leads and around the sensor region, without compromising the function of the protected leads. Furthermore, this semiconductor sensor component has the advantage that a separate measuring instrument is not necessary in order to carry out the studies on the sensor chip, since the function of the measuring instrument is already co-integrated into the housing.

In summary, the semiconductor sensor component of at least one embodiment has at least one of the following advantages.
1. Standard materials, for example polyimide, BCB, low-viscosity globtop materials or insulating resins may be used for covering and protecting the leads. They may come directly in contact with the liquids to be measured in the sensor region, without reactions or short circuits of the leads taking place. Furthermore, most known passivation materials are sufficiently inert with respect to the materials being applied and studied. The small height differences due to the flat leads affect the flow conditions in the measuring cavity of the housing over the sensor region to a negligibly small extent.
2. In contrast to wires, the layer-like pasted leads in the form of conductor tracks can be compressed so that, if need be, an elastic seal may be placed directly on the leads.
3. Owing to the serial interface, fully electronic DNA sensors have only a few connections whose leads must have no resistances in the milli-ohm range. It is therefore possible to produce both the leads and the contact terminal surfaces on the lower housing part by the same technique, and in one step with the connections to the sensor chip. Supply lines may in this case be made with greater width and therefore lower impedance than signal lines.

In an example embodiment of the invention, the transition regions are level-compensating plastic bridges on which the flat leads pass from the material of the lower housing part onto the semiconductor material of the sensor chip. The effect advantageously achieved by this is that the leads can be arbitrarily structured and arranged on the lower housing part, rest constantly on a supporting material and are not applied freely suspended, like for example leads made of bonding wires.

A seal may include, for example, a rubber-elastic film material, which is advantageously adapted rubber-elastically to the flat profile of the leads in the region of the flat leads. Such rubber-elastic film material for the seal furthermore has the advantage that the contours of the region to be sealed can be configured arbitrarily.

In another embodiment of the invention, the seal includes a rubber-elastic jet-printed compound, which is applied onto the lower housing part and shields the housing parts wetted by the medium to be studied from the housing parts not to be wetted when the housing is being assembled from the two housing parts. Arbitrary shaping of the seal can likewise be achieved with such a jet-printed sealing compound.

In another embodiment of the invention, the flat leads adhere to the different materials of the lower housing part, the plastic bridges and the sensor chip. Adhesion of the flat leads to the various materials of the semiconductor sensor component facilitates assembly and ensures a reliable electrical connection between contact terminal surfaces on the lower housing part outside the sensor region and the contact surfaces on the semiconductor chip inside the sensor region. The flat leads in this case have a profile thickness of a few micrometers. The minimal height difference, which is caused by the flat leads, facilitates sealing of the housing parts when they are being assembled owing to a corresponding elastic or plastically deformable seal.

In another example embodiment of the invention, the leads are jet-printed structures. These jet-printed or jet-written structures may be produced by a jet printer, such as is used as an inkjet printer for the production of printed documents. To this end a highly volatile solvent is added to the metal-containing pasted compound for the conductor tracks of the leads, in order to improve the viscosity so as to provide a mobile liquid which can be applied by the jet printing technique, the solvent evaporating and leaving metallic pasted leads behind after the leads have been printed.

In another embodiment of the invention, the flat leads are formed by template-printed structures. To this end, the metal-containing pasted mass of the conductor tracks may be made thicker or more viscous. Since the insulating cover of the flat leads has a thickness of only a few micrometers in the sealed sensor region, a ductile or plastically deformable sealing compound may be placed over this cover without compromising the effectiveness of the seal. This cover is made of a material which is resistant to the media to be studied in the sensor region.

A material which is known as metal paste may preferably be used for the leads. One widespread and proven metal paste is silver metal paste, which can be applied by way of the jet printing technique or template printing technique. Metal pastes which contain copper, gold, palladium and/or aluminum may furthermore be used.

As already mentioned above, the semiconductor component may include a biochemical sensor, preferably a DNA sensor, since an entire microanalysis system can be fitted between the two housing halves. In the case of a microanalysis system, many sensor regions sealed from one another are arranged flatly next to one another, each of the sensor regions including at least one opening on the upper housing side and having a cavity above the sensor region, which can be filled via this opening with a sample material to be analyzed. Besides the fluid test materials, the semiconductor sensor component may also comprise a gas sensor or a pressure sensor, which test physical parameters of the environment.

In another embodiment of the invention, the upper housing part includes not only an opening for filling the cavity above the sensor region but also an inlet opening and an outlet opening, so that fluid can be fed over the sensor region.

The housing may be held together by way of clamp devices, in which case corresponding clamps are fixed securely over both housing parts, i.e. the upper housing part and the lower housing part, with the sealing part arranged between them. This clamping may also be ensured by snap connection using a corresponding design of elastic elements. It is furthermore possible for the housing to comprise an adhesive bead, which preferably comprises a shrinking adhesive, outside the seal. This has the advantage that when the adhesive sets, it shrinks and therefore exerts the application pressure for the sealing part between the upper housing part and the lower housing part. Arranging these adhesive compounds outside the seal furthermore has the advantage that the sensitive sensor surface remains protected by the seal arranged in-between against contaminations by solvent evaporating from the adhesive compound.

A method for producing a semiconductor sensor component having a sensor chip and protective leads includes the following production steps.

First, a lower housing part and an upper housing part are produced. A sensor chip with contact surfaces in the sensor region of the sensor chip is subsequently introduced in the lower housing part. After having introduced the sensor chip, material bridges are produced for level compensation and so as to fill the transitions between the sensor chip and the lower housing part. Flat leads to the contact surfaces are lastly applied both onto the material bridge, and onto the lower housing part as well as onto the sensor chip. The flat leads are subsequently protected in the region of the sensor chip by applying an insulated cover onto the flat leads. The upper housing part may subsequently be applied while connecting the two housing parts so as to compress the seal between the two housing parts.

This method can be carried out with standard technologies and is suitable for mass production, so that inexpensive semiconductor sensor components can be produced with corresponding sensor regions and enclosing housings. In a preferred version of the method, during production of the upper housing part, inlet and outlet openings for fluid media are provided inside the sealed region in the housing upper part and/or lower part. The inlet and outlet openings may extend to the sensor region while lying opposite one another, in order to achieve optimum wetting of the entire sensor region in the cavity of the housing.

When introducing the sensor chip, an adhesive may furthermore be used which wets the edge sides of the sensor chip for level compensation and forms a flat wetting meniscus to the lower housing part. Such an adhesive has the advantage that the level compensation between the upper side of the semiconductor chip and the upper side of the lower housing part is already compensated for by the adhesive, and the positioning of an additional material as a plastic bridge around the semiconductor chip can be obviated.

Should such level compensation by way of a material bridge be necessary, then a dispersion method will be used for this. Either a jet printing method, a dispensing method, a pad or template printing method may be used for applying the flat leads. All the methods have their advantages and disadvantages, and the method employed will depend on the respective application pressure and the precision. During this application of the flat leads, a greater width may be provided for supply lines than for signal lines. This wider application may be achieved both with the jet printing method and with the template printing method.

Printing methods may also be used for application of the insulating cover, so that identical technologies are employed for the entire structure of the leads with the cover. After the seal has been applied onto the lower housing part, a shrinking adhesive may then be applied outside the seal. This has the advantage that the risk of contaminating the sensor surface inside the sealing region is avoided and, on the other hand, the shrinking adhesive already mentioned above has the advantage that the application pressure can be exerted on the seal when the shrinking adhesive sets, without additional clamp elements having to press the lower housing part and the upper housing part onto one another.

Instead of an adhesive technique, ultrasound bonding may also be carried out if the material of the housing parts is suitable for this. Furthermore, it is possible to assemble the two housing parts on one another by means of a soldering technique or by way of laser welding. This soldering technique will advantageously be used when the housing parts are made of ceramic and a corresponding solderable coating is provided in the assembly joint. The laser welding technique will preferably be used for housing parts made of plastic, in order to connect the upper housing part hermetically to the lower housing part. In order to prevent welding gases thereby formed from coating the sensitive sensor region of the semiconductor chip, the seal is preferably already fitted before the laser welding.

### BRIEF DESCRIPTION OF THE DRAWINGS

Example embodiments of the invention will now be explained in more detail with the aid of the appended figures.

FIG. 1 shows a schematic plan view of the semiconductor sensor component of a first embodiment of the invention;

FIG. 2 shows a schematic cross section through a semiconductor sensor component of a second embodiment of the invention;

FIG. 3 shows a schematic cross section through a protected lead to a sensor region of the semiconductor sensor component of a third embodiment of the invention.

### DETAILED DESCRIPTION OF THE EXAMPLE EMBODIMENTS

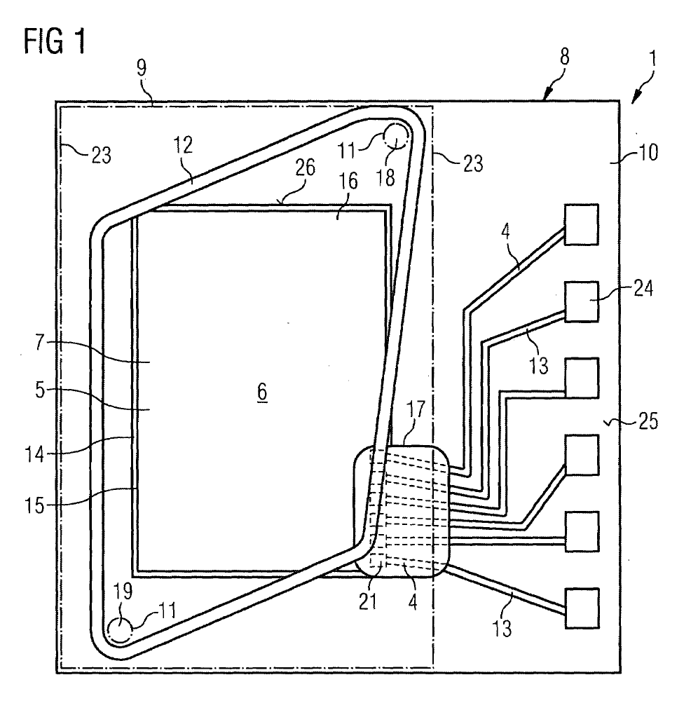

FIG. 1 shows a schematic plan view of the semiconductor sensor component 1 of a first embodiment of the invention. For better understanding of the embodiment, the upper housing part has been removed from the semiconductor sensor component 1. A dot-and-dash line 23 denotes the contour of the upper housing part 9. The lower housing part 10 is partially covered by the upper housing part 9 when it is fitted onto the lower housing part 10 in the region of the dot-and-dash contour.

That region of the upper side 25 of the lower housing part 10 which is not covered by the upper housing part 9 has a row of contact terminal surfaces 24, which can be externally accessed. From the contact terminal surfaces 24, leads 4 in the form of flat printed metal-containing conductor tracks 13 extend to the contact surfaces 21 on the sensor surface 6 of the sensor chip 5. The leads 4 bridge a transition region 14 between the upper side 25 of the lower housing part 10 and the upper side 7 of the sensor chip 5.

The sensor chip 5 is arranged in a recess 26 of the lower housing side 10, and the transition 14 between the lower housing part 10 and the upper side 7 of the sensor chip 5 is filled with a plastic bridge 15. The flat leads 4 thus rest first on the material of the lower housing part 10, which is made of plastic in this embodiment of the invention, and the material of the transition region 14, as well as the material of the upper side 7 of the sensor chip 5. The material of the sensor chip 5 may comprise a passivating oxide layer in which contact holes are made, so that the leads 4 contact the semiconductor material of the sensor chip 5. The material of the flat leads 4 therefore adheres to four different materials and at the same time compensates for thermal stresses of the materials relative to one another in the region of the leads 4, so that no breaking of the leads 4 takes place. To this end, the printed metal-containing pasted material is sufficiently ductile and adhesive so that it can bridge the thermal expansion differences of the four different materials without a line interruption.

The leads 4 are protected by an insulating cover 17 in the sensor region 16, the thickness of the insulating cover 17 and the thickness of the flat leads 4 being so small that the seal 12 can be laid over this region. The seal 12 encloses a region which covers the sensor surface 6, parts of the cover 17 and furthermore the region of the openings 11 in the upper housing part, which serve as an inlet opening 18 and an outlet opening 19. The inlet opening 18 and the outlet opening 19 are arranged lying diagonally opposite to the sensor surface 6, which ensures that a fluid which is introduced into the entry opening 18, and which is taken out from the output opening 19, can wet the sensor surface uniformly.

The seal 12 may be formed by jet printing or consist of a rubber-elastic film which without difficulty hermetically bridges the small height differences that result from the insulating cover 17 and the flat leads 4. Before applying the upper housing part 9 with the inlet opening 18 and the outlet opening 19, a shrinking adhesive for an adhesive bead is applied onto the upper side 25 of the lower housing part 10 around the seal 12. This shrinking adhesive connects the upper housing side 9 to the lower housing side 10 and provides an application pressure on the seal 12 when the shrinking adhesive sets.

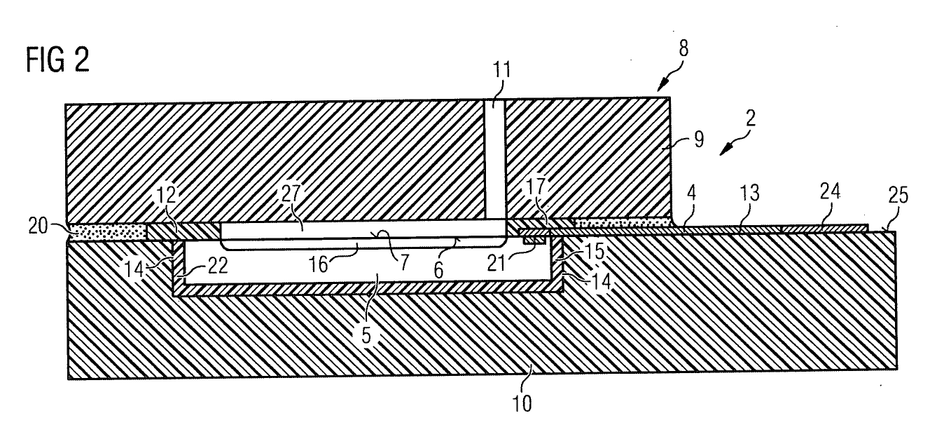

FIG. 2 shows a schematic cross section through a semiconductor sensor component 2 of a second embodiment of the invention. In the second embodiment of the invention as well, the housing 8 is in two parts and comprises an upper housing part 9 and a lower housing part 10 which, by means of a seal 12, seal a cavity 27 which can be filled through an opening 11 with a liquid or gaseous medium to be studied. The application pressure between the upper housing side 9 and the lower housing side 10 on the seal 12 is applied by a shrinking adhesive which is arranged in an adhesive bead 20 outside the seal 12. This arrangement avoids contamination of the upper side 7 of the sensor chip 5 in the region of the sensor surface 6. The conductor tracks 13 emerge from contact terminal surfaces 24 on the upper side 25 of the lower housing part 10 and extend below the adhesive bead 20 and over the transition 14 from the lower housing part 10 to the sensor chip 5. An entire microchemical laboratory can thus be constructed using a simple design, to which end a lower housing part 10 is provided with a multiplicity of sensor regions 16 arranged in rows and columns.

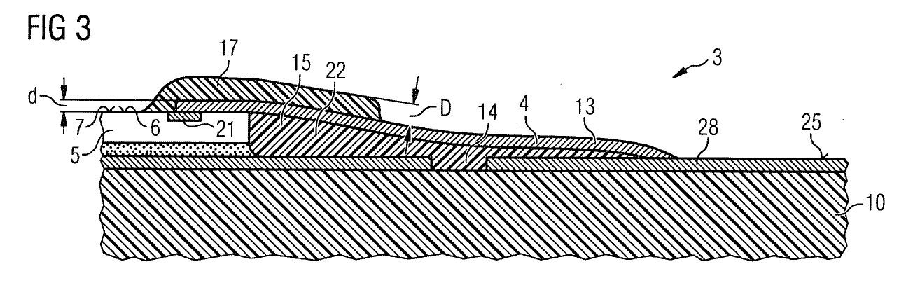

FIG. 3 shows a schematic cross section through a protected lead 4 to a sensor region 6 of a sensor chip 5 of a semiconductor sensor component 3 of a third embodiment of the invention. In order to electrically connect the lead 4 to the sensor chip 5, the sensor chip 5 comprises a contact surface 21. The difference from the previous embodiments is that no recess, into which the sensor chip 5 is placed, is provided in the lower housing part 10. The height difference between the active upper side 7 of the sensor chip 5 and the upper side 25 of the lower housing part 10 is provided by a material bridge 22, a plastic 15 being arranged in the transition region 14, wetting the edge side of the semiconductor chip 5 and forming a flat meniscus on the upper side 25 of the lower housing part 10, so that a flat printed metal-containing conductor track 13 can be applied as a lead 4 with a thickness d from a wiring structure 28 to the contact surface 21.

In a critical region of the lead 4 at the transition onto the sensor chip 5, the lead 4 is protected by an insulated cover 17 having a thickness D of a few micrometers so that aggressive media to be studied cannot attack the lead 4. In the region of the cover 17, a corresponding sealing element is arranged which is in turn so ductile that it can compensate for the height difference between the upper side 25 and the upper side of the insulating cover 17.

Example embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

1. A semiconductor sensor component having protected leads, the semiconductor sensor component comprising:
a sensor chip including a sensor surface on its active upper side and, in a two-part housing including an upper housing part partially covering the sensor chip and a lower housing part carrying the sensor chip, the sensor surface of the sensor chip, between the upper housing part and the lower housing part, is connectable to the environment via at least one opening, in at least one of the upper housing part and in the lower housing part, and a seal, which encloses and protects the sensor surface and covers the leads to the sensor surface, is arranged between the upper housing part and the lower housing part, the leads being metal-containing pasted conductor tracks arranged on the lower housing part and the sensor chip and on transition regions made of different materials and including an insulating cover with a thickness of a few micrometers in the sealed sensor region.

2. The semiconductor sensor component as claimed in claim 1, wherein the transition regions are level-compensating plastic bridges on which the flat leads pass from the material of the lower housing part onto the semiconductor material of the sensor chip.

3. The semiconductor sensor component as claimed in claim 1, wherein the seal includes a rubber-elastic film material, adapted rubber-elastically to the flat profile of the leads in the region of the flat leads.

4. The semiconductor sensor component as claimed in claim 1, wherein a rubber-elastic jet-printed seal is arranged between the upper housing part and the lower housing part.

5. The semiconductor sensor component as claimed in claim 1, wherein the flat leads adhere to the different materials of the lower housing part, the plastic bridges and the sensor chip.

6. The semiconductor sensor component as claimed in claim 1, wherein the flat leads include a profile thickness of a few micrometers.

7. The semiconductor sensor component as claimed in claim 1, wherein the flat leads include jet-printed structures.

8. The semiconductor sensor component as claimed in claim 1, wherein the flat leads include template-printed structures.

9. The semiconductor sensor component as claimed in claim 1, wherein the insulating cover includes a material which is resistant to test media in the sensor region.

10. The semiconductor sensor component as claimed in claim 1, wherein the flat leads include a metal paste.

11. The semiconductor sensor component as claimed in claim 1, wherein the semiconductor sensor component is a DNA sensor.

12. The semiconductor sensor component as claimed in claim 1, wherein the semiconductor sensor component includes a biochemical sensor.

13. The semiconductor sensor component as claimed in claim 1, wherein the semiconductor sensor component includes a microanalysis system.

14. The semiconductor sensor component as claimed in claim 1, wherein the semiconductor sensor component includes a gas sensor.

15. The semiconductor sensor component as claimed in claim 1, wherein the semiconductor sensor component includes a pressure sensor.

16. The semiconductor sensor component as claimed in claim 1, wherein the upper housing part includes an inlet opening and an outlet opening for fluid media.

17. The semiconductor sensor component as claimed in claim 1, wherein the lower housing component includes an inlet opening and an outlet opening for fluid media.

18. The semiconductor sensor component as claimed in claim 1, wherein both the upper housing part and the lower housing part comprise connection openings.

19. The semiconductor sensor component as claimed in claim 1, wherein the housing includes a clamp device which clamps together the upper housing part and the lower housing part with the sealing part arranged between them.

20. The semiconductor sensor component as claimed in claim 1, wherein the housing halves are fixed to one another by snap connections.

21. The semiconductor sensor component as claimed in claim 1, wherein outside the seal, the housing includes an adhesive bead which comprises a shrinking adhesive, which holds together the upper housing part and the lower housing part with the sealing part arranged between them.

22. A method for producing a semiconductor sensor component including a sensor chip and including protected leads, the method comprising:
producing a lower housing part and an upper housing part;
introducing a sensor chip with contact surfaces in a sensor region in the sensor chip in the lower housing part;
producing a material bridge for level compensation so as to fill a transition between the sensor chip and the lower housing part;
applying flat leads to the contact surfaces onto at least one of the material bridge, the lower housing part and the sensor chip;
applying an insulating cover onto the flat leads in the region of the sensor chip;
applying a seal;
applying the upper housing part and connecting the two housing parts so that the seal is compressed.

23. The method as claimed in claim 22, wherein inlet openings and outlet openings for fluid media installed inside the sealed region during the production of at least one of the upper housing part and the lower housing part.

24. The method as claimed in claim 22, wherein, when introducing the sensor chip, an adhesive is used which wets the edge sides of the sensor chip for level compensation and forms a flat wetting meniscus to the lower housing part.

25. The method as claimed in claim 22, wherein a dispensing method is used to produce a material bridge for level compensation.

26. The method as claimed in claim 22, wherein a jet printing method is used for applying flat leads.

27. The method as claimed in claim 22, wherein a template printing method is used for applying flat leads.

28. The method as claimed in claim 22, wherein a pad printing method is used for applying flat leads.

29. The method as claimed in claim 22, wherein, during the application of flat leads, supply leads are applied with a greater width than signal leads.

30. The method as claimed in claim 22, wherein a printing method is used for applying the insulating cover.

31. The method as claimed in claim 22, wherein a shrinking adhesive is applied outside the seal after applying the seal onto the lower housing part.

32. The method as claimed in claim 22, wherein the two housing parts are connected by an adhesive bonding technique.

33. The method as claimed in claim 22, wherein the two housing parts are connected by a clamping technique.

34. The method as claimed in claim 22, wherein the two housing parts are connected by ultrasound bonding.

35. The method as claimed in claim 22, wherein the two housing parts are connected by a soldering technique.

36. The method as claimed in claim 22, wherein the two housing parts are connected by laser welding.

37. The method as claimed in claim 22, wherein the two housing parts are connected by snap connection.

38. The semiconductor sensor component as claimed in claim 2, wherein the seal includes a rubber-elastic film material, adapted rubber-elastically to the flat profile of the leads in the region of the flat leads.

39. The semiconductor sensor component as claimed in claim 10, wherein the metal paste is at least one of a silver, copper, gold, palladium and aluminum metal paste.

40. The method as claimed in claim 23, wherein, when introducing the sensor chip, an adhesive is used which wets the edge sides of the sensor chip for level compensation and forms a flat wetting meniscus to the lower housing part.
